(19) United States
(12) Patent Application Publication
(10) Pub. No.: US 2015/0131231 A1
(43) Pub. Date: May 14, 2015

(54) ELECTRONIC COMPONENT MODULE AND MANUFACTURING METHOD THEREOF

(71) Applicant: SAMSUNG ELECTRO-MECHANICS CO., LTD., Suwon-Si (KR)

(72) Inventors: Do Jae YOO, Suwon-Si (KR); Jong In Ryu, Suwon-Si (KR); Eun Jung Jo, Suwon-Si (KR); Jae Hyun Lim, Suwon-Si (KR); Kyu Hwan Oh, Suwon-Si (KR)

(73) Assignee: SAMSUNG ELECTRO-MECHANICS CO., LTD., Suwon-Si (KR)

(21) Appl. No.: 14/267,456

(22) Filed: May 1, 2014

(30) Foreign Application Priority Data
Nov. 8, 2013 (KR) 10-2013-0135705

(51) Int. Cl. H05K 1/02; H05K 1/11; H05K 3/30; H05K 1/18

(52) U.S. Cl. CPC H05K 1/0215; H05K 1/185; H05K 1/0209; H05K 1/11; H05K 3/30
USPC 361/707; 361/761; 29/841

(57) ABSTRACT

There are provided an electronic component module allowing for a circuit wiring to be disposed outside of a molded part by a plating process, and a manufacturing method thereof, the electronic component module including a substrate; at least one electronic component mounted on the substrate; a molded part sealing the electronic component; a plurality of conductive connectors having one ends bonded to the substrate or one surface of the electronic component and formed in the molded part to penetrate through the molded part; and at least one plane pattern formed on an outer surface of the molded part and electrically connected to at least one of the conductive connectors.

### CROSS-REFERENCE TO RELATED APPLICATIONS

This application claims the priority of Korean Patent Application No. 10-2013-0135705 filed on Nov. 8, 2013, in the Korean Intellectual Property Office, the disclosure of which is incorporated herein by reference.

### BACKGROUND

The present disclosure relates to an electronic component module and a manufacturing method thereof, and more particularly, to an electronic component module allowing for a circuit wiring to be disposed outside of a molded part and a manufacturing method thereof.

The demand for portable devices has recently increased in the area of electronic products. Accordingly, the miniaturization and lightening of electronic components mounted in electronic devices is in continual demand.

In order to realize the miniaturization and lightening of electronic devices, a system on chip (SOC) technology of implementing a plurality of individual elements on a single chip, a system in package (SIP) technology in which a plurality of individual elements are integrated in a single package, or the like, as well as a technology of reducing individual sizes of mounting components may be required.

Meanwhile, in order to manufacture an electronic component module having a small size and high performance, a structure in which electronic components are mounted on both surfaces of a substrate has also been developed.

However, in a case in which electronic components are mounted on both surfaces of a substrate, since molded parts need to be formed on both surfaces of the substrate, the formation of external connection terminals is difficult.

In addition, since electronic devices have recently been designed to have smaller sizes while being integrated and having high degrees of performance, it is preferable to form a power wiring and a ground wiring over a wide area so as to remove bouncing noise from a power supply and a ground, separate analog power and digital power from each other, increase signal integrity in the power supply and the ground, and decrease inductance, or the like.

However, it is relatively difficult to form the power or ground wiring over a wide area in a double-side mounting structure in which molded parts are mounted on both surfaces.

### RELATED ART DOCUMENT

(Patent Document 1) US Patent Laid-Open Publication No. 2012-0320536

### SUMMARY

An aspect of the present disclosure may provide an electronic component module allowing for a circuit wiring to be disposed outside of a molded part and a manufacturing method thereof.

According to an aspect of the present disclosure, an electronic component module may include: a substrate; at least one electronic component mounted on the substrate; a molded part sealing the electronic component; a plurality of conductive connectors having one ends bonded to the substrate or one surface of the electronic component and formed in the molded part to penetrate through the molded part; and at least one plane pattern formed on an outer surface of the molded part and electrically connected to at least one of the conductive connectors.

The molded part may be formed of an epoxy molding compound (EMC).

The at least one conductive connector and the plane pattern may be bonded to the molded part by a plating method.

Each of the conductive connectors may have a horizontal cross-sectional area reduced in size toward the substrate and may include at least one step portion.

The molded part may have a wiring region formed on the outer surface thereof, the wiring region having an increased degree of roughness, and the plane pattern may be plated or printed on the wiring region.

The conductive connectors may include: a first conductive connector connected to an external connection terminal; and a second conductive connector connected to the plane pattern.

The second conductive connector may have one end bonded to a ground pad of the substrate and the plane pattern may serve as a ground surface.

The second conductive connector may have one end bonded to the electronic component mounted on the substrate and the plane pattern may serve as a heat radiating plate.

The at least one plane pattern may include a first plane pattern serving as a ground surface and a second plane pattern serving as a power surface.

The electronic component module may further include a laminated component stacked on the molded part, wherein the at least one plane pattern further includes a third plane pattern serving as an external electrode on which the laminated component is mounted.

The molded part may be provided in plural and the plurality of molded parts may be formed on both surfaces of the substrate, respectively, and the plane pattern may be formed on each of the molded parts.

According to another aspect of the present disclosure, a manufacturing method of an electronic component module may include: preparing a substrate; mounting at least one electronic component on the substrate; forming a molded part sealing the electronic component; forming a wiring region on a surface of the molded part; and forming a plane pattern on the wiring region.

In the forming of the molded part, the molded part may be formed on both surfaces of the substrate.

The forming of the wiring region may include: forming a plurality of via holes in the molded part; and forming the wiring region on an outer surface of the molded part according to a shape of the plane pattern.

In the forming of the wiring region, the via holes and the wiring region may be formed by laser drilling.

The forming of the wiring region may include increasing roughness of an inner surface of each of the via holes and the wiring region using a laser beam.

The forming of the via holes may include forming at least one horizontally-extending surface in each of the via holes due to a step portion formed on the via hole.

The forming of the plane pattern may include forming a conductive connector in each of the via holes using a mechanical interlocking mechanism; and forming the plane pattern on the wiring region.

In the forming of the plane pattern on the wiring region, the plane pattern may be formed by a plating method or a printing method.

According to another aspect of the present disclosure, a manufacturing method of an electronic component module may include: preparing a substrate having at least one component sealed by a molded part; forming a region to be plated on an outer surface of the molded part, the region having an increased degree of roughness; and plating the region.

In the forming of the region to be plated, the region to be plated may be formed to have an average roughness Ra of 5 μm or more.

In the plating of the region, a plane pattern may be formed on the region to be plated to have a thickness of 10 μm or more.

The manufacturing method may further include, after the plating of the region, forming a dielectric layer on the plated region; exposing a portion of the dielectric layer to expose an external electrode pad of the substrate; and forming an external connection terminal on the exposed external electrode pad.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a cross-sectional view schematically illustrating an electronic component module according to an exemplary embodiment of the present disclosure;

FIG. 2 is a partially cut-away perspective view illustrating an inner portion of the electronic component module shown in FIG. 1;

FIG. 3 is a partially enlarged cross-sectional view of part A of FIG. 1;

FIGS. 4A through 4H are cross-sectional views illustrating a manufacturing method of an electronic component module shown in FIG. 1;

FIG. 5 is a cross-sectional view schematically illustrating an electronic component module according to another exemplary embodiment of the present disclosure;

FIG. 6 is a cross-sectional view schematically illustrating an electronic component module according to another exemplary embodiment of the present disclosure; and

FIG. 7 is a cross-sectional view schematically illustrating an electronic component module according to another exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

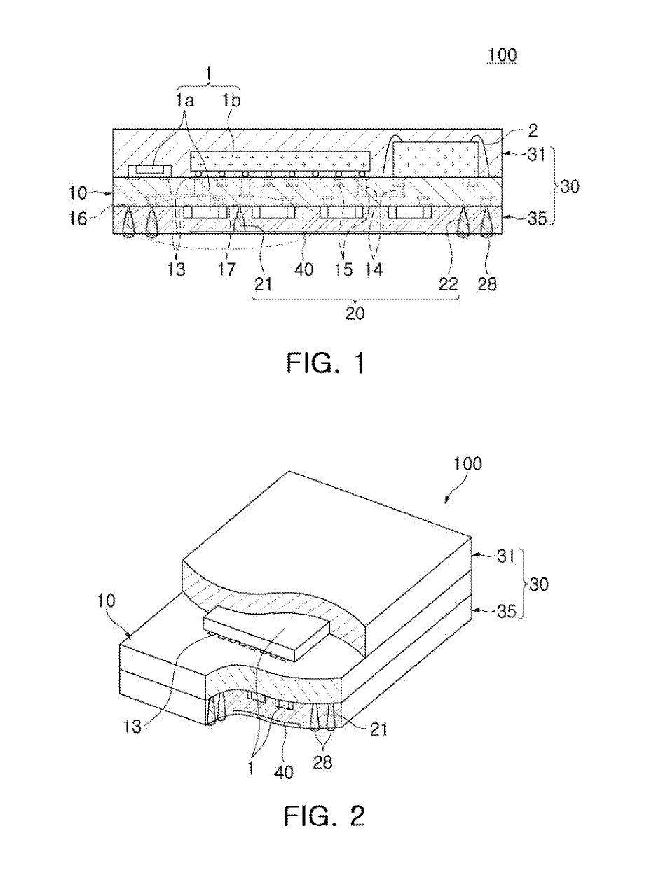

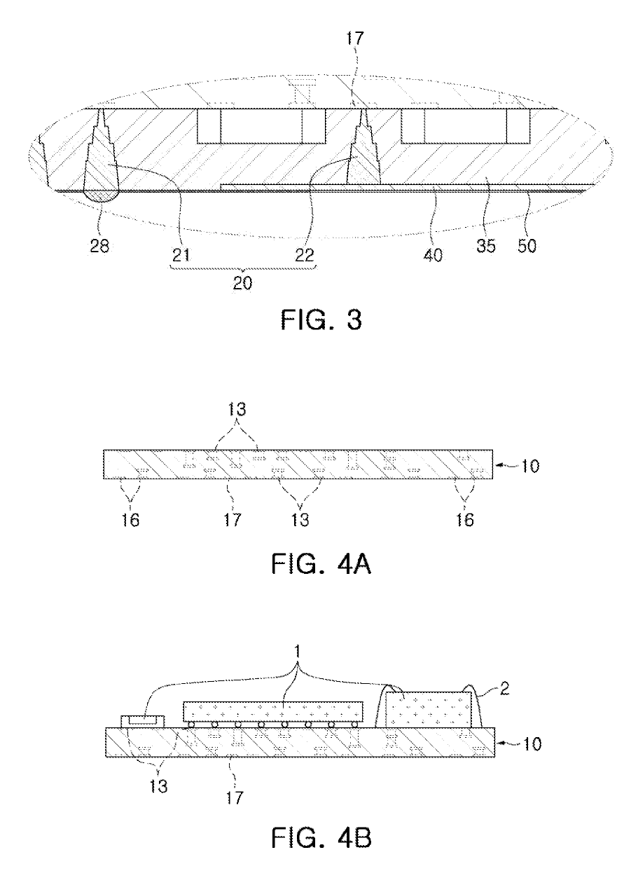

FIG. 1 is a cross-sectional view schematically illustrating an electronic component module according to an exemplary embodiment of the present disclosure. FIG. 2 is a partially cut-away perspective view illustrating an inner portion of the electronic component module shown in FIG. 1 and FIG. 3 is a partially enlarged cross-sectional view of part A of FIG. 1.

Referring to FIGS. 1 through 3, an electronic component module 100 according to the exemplary embodiment of the present disclosure may be configured to include electronic components 1, a substrate 10, molded parts 30, conductive connectors 20, and a plane pattern 40.

The electronic components 1 may include various components such as a passive component 1a and an active component 1b, and all types of components may be used as the electronic components 1, as long as they may be mounted on the substrate.

The electronic components 1 may be mounted on both upper and lower surfaces of the substrate 10 to be described below. FIG. 1 shows a case in which both the active component 1b and the passive component 1a are mounted on the upper surface of the substrate 10 and only the passive component 1a is mounted on the lower surface of the substrate 10, by way of example. However, the present disclosure is not limited to thereto, but the electronic components 1 may be disposed on both surfaces of the substrate 10 in various manners depending on sizes or shapes of the electronic components 1 and a design of the electronic component module 100.

The electronic components 1 may be mounted on the substrate 10 in a flip chip form or may be electrically bonded to the substrate 10 through bonding wires 2.

At least one electronic component 1 may be mounted on at least one surface of the substrate 10. As the substrate 10, various kinds of substrates well known in the art, (a ceramic substrate, a printed circuit board, a flexible substrate, and the like for example), may be used. The substrate 10 may include mounting electrodes 13 or wiring patterns (not shown) formed on one surface or both surfaces thereof. The mounting electrodes 13 are formed to mount the electronic components 1 thereon and the wiring patterns electrically connect the mounting electrodes 13 to each other.

The substrate 10 according to an exemplary embodiment of the present disclosure may be a multilayer substrate including a plurality of layers, and circuit patterns 15 for forming electrical connections may be formed between the respective layers.

In addition, the substrate 10 according to an exemplary embodiment of the present disclosure may include conductive vias 14 electrically connecting the mounting electrodes 13 formed on both surfaces of the substrate 10 and the circuit patterns 15 formed in the substrate 10 to each other.

In addition, the substrate 10 may have an electroplating wiring (not shown) formed on at least one surface thereof. The electroplating wiring may be used in a process of forming the conductive connectors 20 to be described below by electroplating.

In addition, the substrate 10 according to an exemplary embodiment of the present disclosure may include cavities (not shown) formed therein, wherein the cavities allow the electronic components 1 to be embedded in the substrate 10.

In addition, the substrate 10 according to an exemplary embodiment of the present disclosure may have an external connection pad 16 formed on the lower surface thereof. The external connection pad 16 may be configured to be exposed to the outside of the substrate 10. In addition, the external connection pad 16 may be configured such that a portion of the external connection pad 16 is covered with a dielectric material and only another portion thereof is exposed.

The external connection pad 16 may be electrically connected to the conductive connector 20 to be described below and may be connected to an external connecting terminal 28 through the connecting conductor 20.

In addition, the substrate 10 according to an exemplary embodiment of the present disclosure may have a ground pad 17 formed on the lower surface thereof. The ground pad 17 may be electrically connected to the plane pattern 40 to be described below and may be electrically connected to an internal ground of the substrate 10.

The substrate 10 according to an exemplary embodiment of the present disclosure may be a substrate on which a plurality of identical mounting regions are repeatedly disposed in order to simultaneously manufacture a plurality of individual modules, and more particularly, may be a quadrangular substrate having a wide area or an elongated strip shaped substrate. In this case, electronic component modules may be manufactured in a plurality of individual module mounting regions.

The molded parts 30 may include a first molded part 31 formed on the upper surface of the substrate 10 and a second molded part 35 formed on the lower surface of the substrate 10.

The molded parts 30 may seal the electronic components 1 mounted on both surfaces of the substrate 10. In addition, the molded parts 30 may fill spaces between the electronic components 1 mounted on the substrate 10 to prevent electrical short circuits from occurring between the electronic components 1 and may enclose the outside of the electronic components 1 and fix the electronic components 1 onto the substrate 10 to thereby securely protect the electronic components 1 from external impacts.

The molded parts 30 may be formed of an insulating material containing a resin material such as an epoxy or the like, for example, an epoxy molding compound (EMC).

The first molded part 31 according to an exemplary embodiment of the present disclosure may be formed to entirely cover one surface of the substrate 10. In addition, the exemplary embodiment of the present disclosure describes a case in which all the electronic components 1 are embedded in the first molded part 31 by way of example. However, the present disclosure is not limited thereto, but various applications may be made. For example, a portion of at least one of the electronic components 1 may be configured to be exposed to the outside of the first molded part 31.

The second molded part 35 may be formed on the lower surface of the substrate 10 in such a manner that the conductive connectors 20 are embedded in the second molded part 35.

The second molded part 35 may be formed in a manner such that all the electronic components 1 are embedded therein, similar to the first molded part 31, but may also be formed in such a manner that a portion of the electronic components 1 is exposed to the outside.

In addition, the molded parts 30 according to an exemplary embodiment of the present disclosure may include at least one or more via holes 37 and the via holes 37 may have the conductive connectors 20 disposed therein.

The conductive connectors 20 may be bonded to at least one surface of the substrate 10, one ends of thereof may be bonded to the substrate 10, and the other ends thereof may be exposed to the outside of the molded parts 30. That is, the conductive connectors 20 may be formed in the molded parts 30 to penetrate through the molded parts 30.

The conductive connectors 20 according to an exemplary embodiment of the present disclosure may include a first conductive connector 21 connected to the external connection terminal 28 and a second conductive connector 22 connected to the plane pattern 40.

The conductive connectors 20 may be formed of a conductive material and may be formed of copper, silver, aluminum, or an alloy thereof.

Each of the conductive connectors 20 according to an exemplary embodiment of the present disclosure may be formed in a conical shape having a horizontal cross-sectional area reduced in size toward one end thereof, that is, the substrate 10. In this case, the horizontal cross-sectional area of the conductive connector 20 may be gradually reduced in size. As in an exemplary embodiment of the present disclosure, the horizontal cross-sectional area of the conductive connector 20 may be reduced in size in a stepped manner due to the presence of a step portion thereof.

Here, the step portion may be implemented by changing the horizontal cross-sectional area of the conductive connector such that the horizontal cross-sectional area of the conductive connector 20 is increased or decreased.

The other end of the conductive connector 20 may be formed in a flat shape as shown in FIG. 3A. However, the other end of the conductive connector 20 is limited to having a shape such as that illustrated in FIG. 3A. The other end of the conductive connector 20 may be formed to be inwardly concaved as shown in FIG. 3B or may be formed to be convexly protruded to the outside as shown in FIG. 3C. In addition, the flat shape of the conductive connector 20 shown in FIG. 3A may be formed by grinding the conductive connector 20 formed in the concave or convex shape.

The external connection terminal 28 may be bonded to the other end of the first conductive connector 21. The external connection terminal 28 may electrically and physically connect the electronic component module 100 and a main substrate (not shown) on which the electronic component module 100 is mounted to each other. The external connection terminal 28 may be formed in a bump form, but is not limited thereto. For example, the external connection terminal 28 may be formed in various manners. For example, the external connection terminal 28 may be in the form of a solder ball or the like.

The exemplary embodiment of the present disclosure describes a case in which the conductive connectors 20 are formed in the second molded part 35, by way of example. However, the configuration of the present disclosure is not limited thereto. The conductive connectors 20 may be formed in the first molded part 31, if necessary.

The plane pattern 40 may be connected to the other end of the second conductive connector 22. The first conductive connector 21 and the second conductive connector 22 may be formed to have the same structure and the same size. However, they may be formed to have different sizes and different structures, if necessary.

The plane pattern 40 may be formed on an outer surface of the molded part 30 and may be formed by a plating process. However, the present disclosure is not limited thereto, but the plane pattern 40 may also be formed by a printing process using a conductive paste.

The plane pattern 40 may be formed in a wiring form and may be in the form of a power and/or ground plane having a wide area on one surface of the molded part 30 as in an exemplary embodiment of the present disclosure.

The plane pattern 40 may be electrically connected to the substrate 10 by the second conductive connector 22.

The plane pattern 40 and the second conductive connector 22 may be electrically connected to the ground pad 17 of the substrate 10. Therefore, the plane pattern 40 may be used as a ground surface of the electronic component module 100.

According to the exemplary embodiment of the present disclosure, the plane pattern 40 may be formed on an outer surface, that is, a lower surface of the second molded part 35. Therefore, when the electronic component module 100 is mounted on a main substrate 70 illustrated in FIG. 5, the plane pattern 40 may be disposed to face the main substrate.

As a result, noise introduced from the main substrate may be easily shielded. On the other hand, the introduction of noise generated in the electronic component module 100 to the main substrate may also be prevented.

Therefore, in a case in which the plane pattern 40 is used as the ground surface, the plane pattern 40 may be formed on the outer surface of the second molded part 35 in as a large area as possible.

In addition, a dielectric layer 50 for protecting the plane pattern 40 may be formed on an outer surface of the plane pattern 40.

The electronic component module 100 according to an exemplary embodiment of the present disclosure having the configuration as described above may have the electronic components 1 mounted on both surfaces of the substrate 10. In addition, the substrate 10 and the external connection terminal 28 may be electrically connected to each other by the connection conductors 20 disposed on the lower surface of the substrate 10.

As a result, the plurality of electronic components 1 may be mounted on one substrate, thereby increasing a degree of integration of the components.

In addition, according to a double-sided molding structure, the plane pattern 40 may be formed on the outer surface of the molded part 30. Therefore, in a case in which the plane pattern 40 is used as the ground surface, the introduction or emission of electromagnetic waves may be easily shielded and inductance generated in the electronic component module 100 may also be decreased.

Meanwhile, an exemplary embodiment of the present disclosure has described a case in which the plane pattern 40 is formed to have a wide area and is used as the ground surface, by way of example. However, the configuration of the present disclosure is not limited thereto. The plane pattern 40 may also be formed to have a wiring pattern shape, thereby being used as a circuit wiring. The plane pattern 40 may be formed in various manners and various applications thereof may be made. For example, the plane pattern 40 may be formed to have an antenna radiator shape or may be formed in a spiral form, thereby being used as a coil.

In addition, although the exemplary embodiment of the present disclosure describes a case in which a single conductive connector 20 is connected to one plane pattern 40, by way of example, the plurality of conductive connectors 20 may be connected to the plane pattern 40, if necessary.

Next, a manufacturing method of an electronic component module according to an exemplary embodiment of the present disclosure will be described.

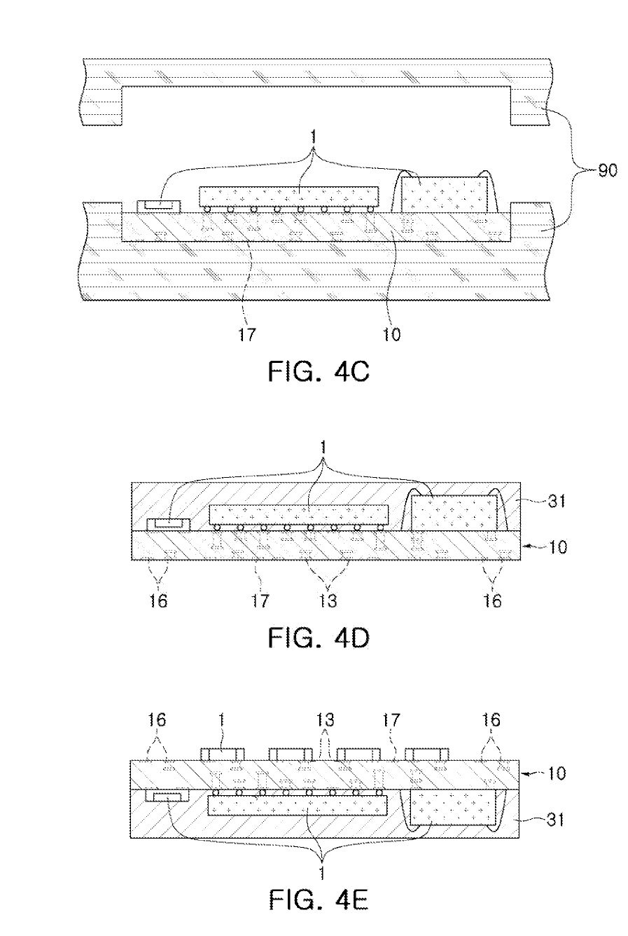

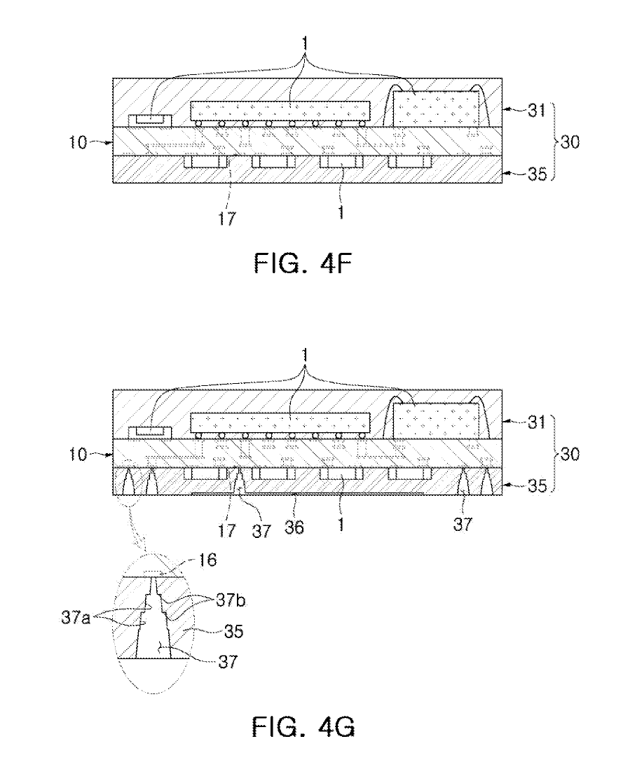

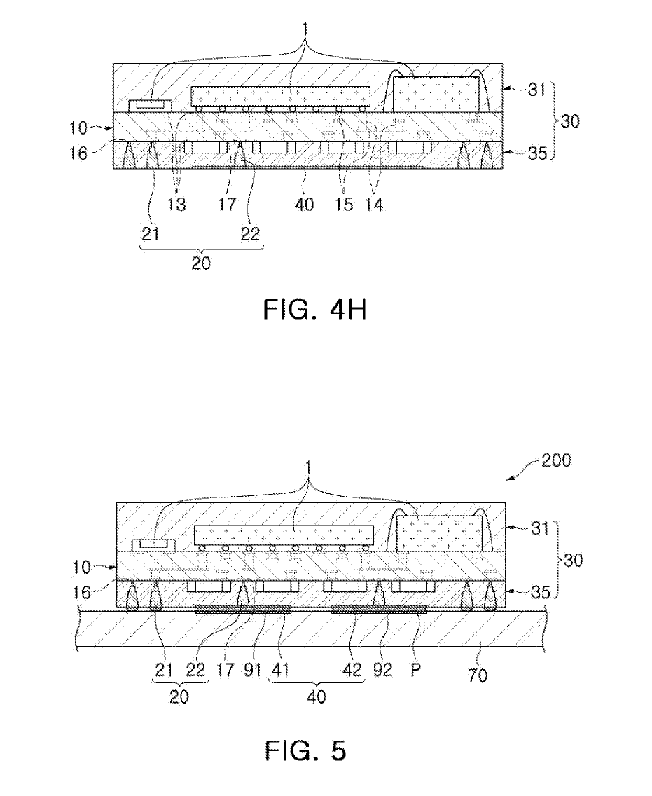

FIGS. 4A through 4h are cross-sectional views illustrating a manufacturing method of an electronic component module shown in FIG. 1.

Referring to FIGS. 4A through 4H, as shown in FIG. 4A, an operation of preparing the substrate 10 is first performed. As described above, the substrate 10 may be a multilayer substrate and may have the mounting electrodes 13 formed on both surfaces thereof. The external connection pad 16 and the ground pad 17 may be formed on the lower surface of the substrate 10.

Next, as shown in FIG. 4B, an operation of mounting the electronic components 1 on one surface, that is, an upper surface of the substrate 10 is performed. The operation of mounting the electronic components 1 may be performed through processes in which a solder paste is printed on the mounting electrodes 13 formed on one surface of the substrate 10 by a screen printing method, or the like, the electronic components 1 are seated on the printed solder paste, and then the solder paste is cured by applying heat thereto.

However, the operation of mounting the electronic components 1 is not limited thereto, but may be performed through processes in which the electronic components 1 are seated on one surface of the substrate 10, and the mounting electrodes 13 formed on the substrate and electrodes of the electronic components 1 are then electrically connected to each other by the bonding wires 2.

Next, an operation of forming the first molded part 31 on one surface of the substrate 10 is performed. In the operation of forming the first molded part 31, as shown in FIG. 4C, an operation of disposing the substrate 10 having the electronic components 1 mounted thereon in a mold 90 is first performed.

Next, the first mold part 31 is formed by injecting a molding resin into the mold 90. As a result, as shown in FIG. 4D, the electronic components 1 mounted on one surface, that is, the upper surface of the substrate 10 may be protected from the outside by the first molded part 31.

Next, as shown in FIG. 4E, an operation of mounting the electronic components 1 on the lower surface of the substrate 10 is performed. The operation of mounting the electronic components 1 may be performed through processes in which a solder paste is printed on the mounting electrodes 13 by a screen printing method, or the like, the electronic components 1 are seated on the printed solder paste, and the solder paste is then cured by applying heat thereto.

Next, as shown in FIG. 4F, an operation of forming the second molded part 35 on the lower surface of the substrate 10 is performed. The operation of forming the second molded part 35 may be performed by disposing the substrate 10 in the mold 90 and then injecting the molding resin into the mold 90, similar to the case shown in FIG. 4C.

Next, a region to be plated may be formed. The region to be plated according to an exemplary embodiment of the present disclosure may include an inner surface of the at least one via hole 37 and a wiring region of the plane pattern 40.

First, as shown in FIG. 4G, the via hole 37 is formed in the second molded part 35. The via hole 37 may be formed by a laser drilling method.

In the process of forming the via hole 37, the via hole 37 may be formed to have a conical shape having a horizontal cross-sectional area reduced in size toward the substrate 10. In addition, the via hole 37 may be formed in such a manner that the horizontal cross-sectional area thereof may be reduced in size in a stepped manner due to the presence of a step portion thereof.

Therefore, the via hole 37, according to an exemplary embodiment of the present disclosure may include side walls 37a disposed in a substantially vertical direction and at least one horizontally-extending surface 37b formed such that the horizontal cross-sectional area of the via hole 37 is increased or decreased, from the side wall 37a.

The via hole 37 according to an exemplary embodiment of the present disclosure may be implemented by forming a spot size of a laser beam to be smaller than a size of one end of the via hole 37 and irradiating the laser onto the molded part 30.

For example, laser is first irradiated onto a central portion of the via hole 37 and a position from which the laser beam is irradiated is then moved, such that a shape of the via hole 37 according to an exemplary embodiment of the present disclosure may be formed.

The structure of the via hole 37 described above may be configured to secure mechanical anchoring force between a plating material formed during a process of forming the conductive connectors 20 to be described below and the via hole 37.

The molded parts 30 according to an exemplary embodiment of the present disclosure may be formed of an EMC. It is generally known that it is difficult to perform a plating process, that is, a metal bonding process on a surface of an EMC formed of a thermosetting resin.

Therefore, the manufacturing method according to an exemplary embodiment of the present disclosure may use a mechanical interlocking mechanism, a hooking or anchoring theory or an anchoring effect in order to plate a conductor on the surface of the EMC. This means a mechanism in which an adhesive penetrates into an irregular structure (concave and convex structure) on a surface of an object to have the adhesive adhered thereto, such that the adhesive and the object may be bonded to each other by mechanical engagement.

That is, the manufacturing method according to an exemplary embodiment of the present disclosure may use a method in which an inner surface of the via hole 37 formed of the EMC is roughly formed as much as possible and a plating material is coupled to the inner surface of the via hole 37 by the anchoring effect in the plating process.

To this end, according to an exemplary embodiment of the present disclosure, an irregular structure is formed by increasing an inner surface roughness of the via hole 37 as much as possible during a process of forming the via hole 37 using a laser beam. Here, the surface roughness may be increased by adjusting kinds or spot sizes of laser beams and power of laser beams.

Meanwhile, since the side walls 37a of the via hole 37 may be vertically formed or may be significantly inclined, there is a limitation in increasing the roughness using only laser. Therefore, the manufacturing method of the electronic component module according an exemplary embodiment of the present disclosure may form a step portion on the via hole 37 and form the horizontally-extending surface 37b which is a surface substantially perpendicular to a direction in which the laser beam is irradiated.

The horizontally-extending surface 37b may be formed as a surface perpendicular to a direction in which the laser beam is irradiated, but is not limited thereto. For example, the horizontally-extending surface 37b may also be formed of an inclined surface. That is, the horizontally-extending surface 37b according to an exemplary embodiment of the present disclosure may be defined as a surface formed to be almost perpendicular to the direction in which the laser beam is irradiated, as compared to the side walls 37a.

Since the laser spot may be irradiated on the horizontally-extending surface 37b as much as possible as compared to the side walls 37a, the inner surface of the via hole 37 may have further increased roughness.

As a result of measuring an average roughness Ra of the horizontally-extending surface 37b and the side wall 37a formed by a laser beam (e.g., UV laser), in a case in which the average roughness of the side wall 37a was 5.49 μm, the average roughness of the horizontally-extending surface 37b was 12.51 μm. That is, in the case of using a laser beam, degrees of the roughness between the horizontally-extending surface 37b and the side wall 37a are significantly different. As a result, it may be appreciated that the horizontally-extending surface 37b is a very important factor in performing the plating process.

When the average roughness Ra was approximately 5 μm or more, the plating process could be performed. However, since mechanical anchoring force was insufficiently ensured, it is difficult to stably bond a plating material to the inner surface of the via hole 37 in a case in which the horizontally-extending surface 37b is not present.

Therefore, the via hole 37 according to an exemplary embodiment of the present disclosure may include the horizontally-extending surface 37b having the average roughness of 12 μm or more. In a case in which the average roughness Ra is 12 μm or more, since bonding and plating operations between heterogeneous interfaces are stably performed, plating and bonding reliability in the via hole 37 may be increased.

As described above, the via hole 37 according to an exemplary embodiment of the present disclosure may be formed to have the average roughness Ra of 5 μm or more and may include at least one horizontally-extending surface 37b formed to have the average roughness of 12 μm or more.

In addition, an overall inclined angle (θ) of the side wall 37a with respect to a horizontal surface (or one surface of the substrate) may be 25° to 90°. In a case in which the inclined angle (θ) is 25° or less, it may be difficult to perform the laser drilling process and in a case in which the inclined angle (θ) is 90° or more, it may be difficult to form the horizontally-extending surface 37b.

Meanwhile, in a case in which it is difficult to obtain an optimal roughness only using a laser beam, an etching process may be additionally performed. That is, the roughness may be further increased by injecting an etchant into the via hole 37 and removing it from the via hole 37 after a predetermined time is elapsed.

Meanwhile, as described above, the conductive connectors 20 according to an exemplary embodiment of the present disclosure may include the first conductive connector 21 and the second conductive connector 22. Therefore, the via hole 37 may also include the via hole 37 for forming the first conductive connector 21 and the via hole 37 for forming the second conductive connector 22.

Here, the via hole 37 for forming the first conductive connector 21 may be formed at a position corresponding to the external connection pad 16 of the substrate 10 and the via hole 37 for forming the second conductive connector 22 may be formed at a position corresponding to the ground pad 17 of the substrate 10.

In addition, in the operation of forming the via hole 37, a wiring region 36 for forming the plane pattern 40 to be described below may be formed.

The wiring region 36 may be formed over the entirety of a region on which the plane pattern 40 is formed and may be defined as a region in which roughness thereof is increased by the laser beam.

That is, in the manufacturing method according to an exemplary embodiment of the present disclosure, the via hole 37 may be formed using the laser beam and the laser beam is irradiated onto the outer surface of the second molded part 35 according to a shape of the plane pattern 40 to thereby increase the surface roughness of the corresponding wiring region 36. The wiring region 36 may also be formed to have the surface roughness of 12 μm or more, similar to the horizontally-extending surface 37b of the via hole 37.

Therefore, the wring region 36 may be formed in a groove form as in an exemplary embodiment of the present disclosure. However, the shape of the wiring region 36 is not limited thereto, but may be formed such that only roughness thereof is changed on a plane rather than in the groove.

Next, as shown in FIG. 4H, the conductive connectors 20 and the plane pattern 40 are formed.

First, the first and second conductive connectors 21 and 22 are formed in at least one or more via holes 37. Sequentially, the plane pattern 40 is formed on the wiring region 36 of the second molded part 35.

Both the conductive connectors 20 and the plane pattern 40 may be formed by the plating process. When the conductive connectors 20 and the plane pattern 40 are formed of a copper (Cu) material, a copper plating process may be performed. In addition, the plating process may include an electroless plating process and an electroplating process, but is not limited thereto.

For example, the conductive connectors 20 and the plane pattern 40 may also be formed by only performing the electroplating process. In this case, the conductive connectors 20 and the plane pattern 40 may be formed by sequentially filling the via holes 37 sequentially from the external electrode terminal 16 of the substrate 10 using an electroplating wiring (not shown) formed on the substrate 10.

As described above, since the conductive connectors 20 and the plane pattern 40 according to an exemplary embodiment of the present disclosure are formed on an EMC surface, it is difficult to perform the metal bonding process. However, in the manufacturing method according to an exemplary embodiment of the present disclosure, since degrees of roughness on the inner surface of the via hole 37 and the wiring region 36 may be formed as high as possible, even in a case in which the molded part is formed of an EMC material, the conductive connectors 20 and the plane pattern 40 may be formed in the via hole 37 or on the outer surface of the second molded part 35 in such a manner that bonding between the heterogeneous interfaces may be facilitated.

In addition, in the manufacturing method according to an exemplary embodiment of the present disclosure, a plating operation may be performed only on necessary portions (e.g., the inner surface of the via hole and the region to be plated) in the plating process. A detailed description thereof will be provided below.

As describe above, since a metal material is not easily bonded to the EMC surface, even in a case in which a plating solution is applied onto the overall surface of the molded parts 30 during the plating process, a plating layer is not easily formed and plating is performed only on portions having a threshold roughness or greater, that is, on the inner portion of the via hole 37 and the wiring region 36.

Therefore, since the plating layer is not formed on an unnecessary portion, a process of removing the plating layer formed on the unnecessary portion is not required and the amount of use of the plating solution may be significantly decreased, such that manufacturing costs and time may be decreased.

Meanwhile, in this process, in order to increase coupling force between the conductive connectors 20 and the molded parts 30, a catalytic metal such as gold, platinum, palladium, or the like is first disposed on a plating target region and substantial copper plating may be then performed.

In addition, the present disclosure is not limited thereto. Various modifications may be made. For example, the conductive connectors 20 are first formed by a plating method and a conductive paste is applied onto the wiring region 36 by a printing method, thereby forming the plane pattern 40.

In addition, an operation of forming the dielectric layer (50 of FIG. 3) for protecting the plane pattern 40 on the outer surface of the plane pattern 40 may be further performed.

In a case in which the conductive connectors 20 and the plane pattern 40 are formed according to the operations described above, the external connection terminal 28 is formed on the other end of the first conductive connector 21, such that the electronic component module 100 according to an exemplary embodiment of the present disclosure as shown in FIG. 1 may be completed.

Here, the external connection terminal 28 may be formed in various manners. For example, the external connection terminal 28 may be formed in a bump shape, a solder ball shape, or the like, and may be omitted, if necessary.

The electronic component module 100 according to an exemplary embodiment of the present disclosure manufactured by the operations described above may have the electronic components 1 mounted on both surfaces of the substrate 10, and all of the electronic components 1 may be sealed by the molded parts 30. Therefore, the plurality of components may be mounted in a single electronic component module 100 and may be easily protected from outside.

In addition, the conductive connectors 20 and the plane pattern 40 may be formed in the molded parts 30 by the plating method. Therefore, a conductor path connecting the substrate 10 and the outside to each other and the circuit wirings may be very easily implemented and manufactured even in the double-sided molding structure.

In addition, since the conductive connectors 20 and the plane pattern 40 may be selectively formed only in desired locations by the plating method, manufacturing costs and time may be significantly decreased.

In addition, since the plating method is used, the via hole 37 and the plane pattern 40 may be easily and precisely formed as compared to the case of the related art using a conductive paste, even in the case the via hole 37 has a fine size and the plane pattern 40 has a fine line width.

Meanwhile, although the exemplary embodiment of the present disclosure describes a case in which the first molded part 31 is first formed and subsequently, the second molded part 35 is formed, by way of example, the configuration of the present disclosure is not limited thereto. Various applications may be made. For example, the second molded part 35 may be first formed, or the first and second molded parts 31 and 35 may be formed simultaneously.

FIG. 5 is a cross-sectional view schematically illustrating an electronic component module according to another exemplary embodiment of the present disclosure.

Referring to FIG. 5, an electronic component module 200 according to another exemplary embodiment of the present disclosure may include two plane patterns 41 and 42. However, the configuration of the present disclosure is not limited thereto, but various applications of the configuration may be made. For example, two or more plane patterns 40 may be formed.

The plane pattern 40 according to another exemplary embodiment of the present disclosure may include a first plane pattern 41 used as a ground surface and a second plane pattern 42 used as a power surface. That is, the first and second plane patterns 41 and 42 according to another exemplary embodiment of the present disclosure may be formed as a ground terminal and a power terminal, thereby being used as a channel providing power to the electronic component module.

Since the first and second plane patterns 41 and 42 may be formed to have a relative large area compared to external connection terminals 28, they may be easily utilized for the power and ground terminals to which a relatively high voltage is applied.

Therefore, the first and second plane patterns 41 and 42 may be electrically connected to the main substrate 70 by a conductive adhesive P, or the like. In this case, a ground pad 91 and a power pad 92 may be formed on one surface of the main substrate 70 and may be electrically connected to the first and second plane patterns 41 and 42.

The plane pattern 40 according to another exemplary embodiment of the present disclosure as described above may serve as the ground surface for shielding electromagnetic waves or decreasing inductance as well as serving as the terminal connected to the main substrate 70.

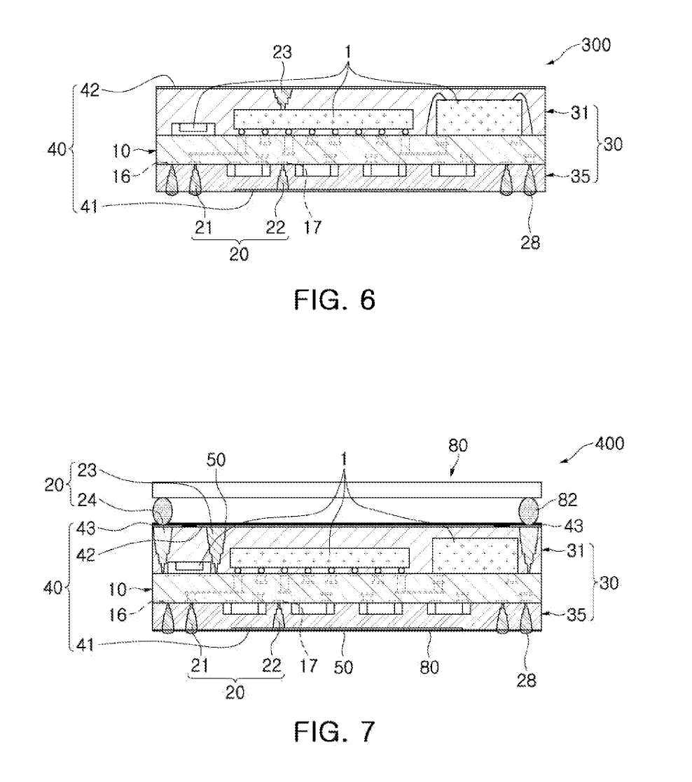

FIG. 6 is a cross-sectional view schematically illustrating an electronic component module according to another exemplary embodiment of the present disclosure.

Referring to FIG. 6, a power component module 300 according to another exemplary embodiment of the present disclosure may include the first plane pattern 41 formed on the second molded part 35 and the second plane pattern 42 formed on the first molded part 31.

The first plane pattern 41 according to another exemplary embodiment of the present disclosure may be connected to the ground pad 17 of the substrate 10 through the second conductive connector 22 of the second molded part 35 and the second plane pattern 42 may be connected to one surface of the electronic component 1 through a third conductive connector 23 of the first molded part 31.

The second plane pattern 42 according to another exemplary embodiment of the present disclosure may be used as an electromagnetic shielding plate and may be also used as a heat radiating plate.

Therefore, heat generated from the electronic component 1 may be delivered to the second plane pattern 42 along the third conductive connector 23 and may be radiated to the outside.

Meanwhile, the first plane pattern 41 according to another exemplary embodiment of the present disclosure may serve as a ground surface similarly to the above described exemplary embodiment and may be configured to serve as a heat radiating plate similarly to the second plane pattern 42.

FIG. 7 is a cross-sectional view schematically illustrating an electronic component module according to another exemplary embodiment of the present disclosure.

Referring to FIG. 7, an electronic component module 400 according to another exemplary embodiment of the present disclosure may have a configuration similar to that of the electronic component module of FIG. 6 as described above and may have at least one laminated component 80 stacked on the first molded part 31.

The laminated component 80 may be a general electronic component and may include at least one external terminal 82 on a lower surface thereof. The external terminal 82 of the laminated component 80 may be bonded to a third plane pattern 43 to be described below.

In addition, the power component module 400 according to another exemplary embodiment of the present disclosure may include the first plane pattern 41 formed on the second molded part 35, and the second plane pattern 42 and the third plane pattern 43 formed on the first molded part 31.

In addition, the conductive connectors 20 according to another exemplary embodiment of the present disclosure may include the first conductive connector 21 and the second conductive connector 22 formed in the second molded part 35, the third conductive connector 23 formed in the first molded part 31 and connected to the second plane pattern 42, and a fourth conductive connector 24 formed in the first molded part 31 and connected to the third plane pattern 43.

The third plane pattern 43 according to another exemplary embodiment of the present disclosure may be in a form of an electrode pad covering an end portion of the fourth conductive connector 24 and may be connected to the external terminal 82 of the laminated component 80 stacked thereon while not being connected to a power supply or a ground.

The third plane pattern 43 according to another exemplary embodiment of the present disclosure may be used as an I/O terminal or an external electrode pad connected to another electronic component or module other than the laminated component 80.

In addition, the first and second plane patterns 41 and 42 according to another exemplary embodiment of the present disclosure may have an insulating layer or the dielectric layer 50 formed on an outer surface thereof.

In this case, the dielectric layer is formed on the entire outer surface on which the first, second, and third plane patterns 41, 42, and 43 are formed, a portion of the dielectric layer corresponding to a location on which the third plane pattern 43 is formed may be removed and exposed to the outside, and subsequently, the external terminal 82 of the laminated component 80 may be bonded to the exposed portion.

In the electronic component module 400 according to another exemplary embodiment of the present disclosure, the plane patterns 41, 42, and 43 may be collectively formed on both surfaces of the molded parts by a single plating process even in a case in which the plane patterns 40 are formed on both of the first molded part 31 and the second molded part 35, the electronic component module 400 may be easily manufactured.

However, various applications may be made in forming the plane patterns. For example, the plane patterns 41, 42, and 43 may be formed of a conductive film or a conductive paste.

As set forth above, the electronic component module according to exemplary embodiments of the present disclosure may have electronic components mounted on both surfaces of a substrate and all of the electronic components may be sealed by a molded part. Therefore, the plurality of components may be mounted in a single electronic component module and may be easily protected from the outside.

A conductive connector may be formed in a via hole formed in the molded part by a plating method. Therefore, a conductor path connecting the substrate and the outside to each other may be easily implemented and manufactured even in a double-sided molding structure.

In addition, since the conductive connector may be formed only in a desired portion by the plating method, manufacturing costs and time may be significantly decreased.

In addition, since the plating method is used, the conductive connector may be easily formed in the via hole as compared to a process using a conductive paste according to related art even in a case in which the via hole has a micro-size.

In addition, since the conductive connector is bonded to the inner surface of the via hole by the mechanical anchoring effect due to roughness of a laser processed surface, even in a case in which delamination occurs in the interface between the connector and the inner surface, the expansion of the delamination to a crack may be prevented.

In addition, since the plating method is used, ground and power plane patterns having large areas may be easily formed.

In addition, in a case in which the plane patterns are used as ground and power planes, impedance matching and inductance may be decreased, thereby removing the occurrence of noise.

In addition, the power plane may increase integrity of power distribution and may allow for the effective distribution of analog and digital power.

In addition, a bonding area between a large area external connection terminal of the power plane pattern and a mother board may be increased, thereby increasing adhesion strength and reliability against impacts.

While exemplary embodiments have been shown and described above, it will be apparent to those skilled in the art that modifications and variations could be made without departing from the spirit and scope of the present disclosure as defined by the appended claims.

What is claimed is:

1. An electronic component module, comprising:
a substrate;
at least one electronic component mounted on the substrate;
a molded part sealing the electronic component;
a plurality of conductive connectors having one ends bonded to the substrate or one surface of the electronic component and formed in the molded part to penetrate through the molded part; and
at least one plane pattern formed on an outer surface of the molded part and electrically connected to at least one of the conductive connectors.

2. The electronic component module of claim 1, wherein the molded part is formed of an epoxy molding compound (EMC).

3. The electronic component module of claim 1, wherein the at least one conductive connector and the plane pattern are bonded to the molded part by a plating method.

4. The electronic component module of claim 1, wherein each of the conductive connectors has a horizontal cross-sectional area reduced in size toward the substrate and includes at least one step portion.

5. The electronic component module of claim 1, wherein the molded part has a wiring region formed on the outer surface thereof, the wiring region having an increased degree of roughness, and the plane pattern is plated or printed on the wiring region.

6. The electronic component module of claim 1, wherein the conductive connectors include:
a first conductive connector connected to an external connection terminal; and
a second conductive connector connected to the plane pattern.

7. The electronic component module of claim 6, wherein the second conductive connector has one end bonded to a ground pad of the substrate and the plane pattern serves as a ground surface.

8. The electronic component module of claim 6, wherein the second conductive connector has one end bonded to the electronic component mounted on the substrate and the plane pattern serves as a heat radiating plate.

9. The electronic component module of claim 1, wherein the at least one plane pattern includes a first plane pattern serving as a ground surface and a second plane pattern serving as a power surface.

10. The electronic component module of claim 9, further comprising: a laminated component stacked on the molded part,
wherein the at least one plane pattern further includes a third plane pattern serving as an external electrode on which the laminated component is mounted.

11. The electronic component module of claim 1, wherein the molded part is provided in plural and the plurality of molded parts are formed on both surfaces of the substrate, respectively, and
the plane pattern is formed on each of the molded parts.

12. A manufacturing method of an electronic component module, the manufacturing method comprising:
preparing a substrate;
mounting at least one electronic component on the substrate;
forming a molded part sealing the electronic component;
forming a wiring region on a surface of the molded part; and
forming a plane pattern on the wiring region.

13. The manufacturing method of claim 12, wherein in the forming of the molded part, the molded part is formed on both surfaces of the substrate.

14. The manufacturing method of claim 12, wherein the forming of the wiring region includes:
forming a plurality of via holes in the molded part; and
forming the wiring region on an outer surface of the molded part according to a shape of the plane pattern.

15. The manufacturing method of claim 14, wherein in the forming of the wiring region, the via holes and the wiring region are formed by laser drilling.

16. The manufacturing method of claim 14, wherein the forming of the wiring region includes increasing roughness of an inner surface of each of the via holes and the wiring region using a laser beam.

17. The manufacturing method of claim 14, wherein the forming of the via holes includes forming at least one horizontally-extending surface in each of the via holes due to a step portion formed on the via hole.

18. The manufacturing method of claim 14, wherein the forming of the plane pattern includes:
forming a conductive connector in each of the via holes using a mechanical interlocking mechanism; and
forming the plane pattern on the wiring region.

19. The manufacturing method of claim 18, wherein in the forming of the plane pattern on the wiring region, the plane pattern is formed by a plating method or a printing method.

20. A manufacturing method of an electronic component module, the manufacturing method comprising:
preparing a substrate having at least one component sealed by a molded part;
forming a region to be plated on an outer surface of the molded part, the region having an increased degree of roughness; and
plating the region.

21. The manufacturing method of claim 20, wherein in the forming of the region to be plated, the region to be plated is formed to have an average roughness Ra of 5 μm or more.

22. The manufacturing method of claim 20, wherein in the plating of the region, a plane pattern is formed on the region to be plated to have a thickness of 10 μm or more.

23. The manufacturing method of claim 20, further comprising: after the plating of the region,
forming a dielectric layer on the plated region;
exposing a portion of the dielectric layer to expose an external electrode pad of the substrate; and
forming an external connection terminal on the exposed external electrode pad.
